(19) United States
(12) Patent Application Publication
(10) Pub. No.: US 2012/0063066 A1
(43) Pub. Date: Mar. 15, 2012

(54) ERGONOMIC ACCESSORY FOR USE WITH A PORTABLE ELECTRONIC DEVICE

(76) Inventor: Curtis Floit, San Diego, CA (US)

(21) Appl. No.: 12/882,060

(22) Filed: Sep. 14, 2010

(51) Int. Cl. H05K 5/00; A45F 5/00

(52) U.S. Cl. 361/679.01; 224/218

(57) ABSTRACT

An ergonomic band for attaching to a rear surface of a portable electronic device, or a case configured for attachment with such a device. The ergonomic band may include one or more slits for receiving at least one finger of a user such that the device becomes ergonomically attached to the hand or wrist of a user. Two ergonomic bands may be provided. Each ergonomic band enables relaxation of anatomical features during prolonged use of portable electronic devices. The ergonomic band, or bands, can be attached to a device or device case using an adhesive or mechanical fit, or alternatively the band may conform through a slot pair. In certain embodiments, the ergonomic band can be detached and re-engaged as desired by a user.

### FIELD OF THE INVENTION

This invention relates to accessories for use with portable electronic devices; and more particularly to accessories for providing ergonomic attachment to the anatomical extremities of an electronic device user.

### BACKGROUND OF THE INVENTION

Portable electronic devices have become increasingly popular in recent years with the market release of the iPhone; iPod; iPad; BlackBerry; Kindle; and the like. Personal Digital Assistants (PDAs), such as iPhone and BlackBerry cellular phones, are becoming increasingly popular among everyday users of portable electronics, especially recently with the release of mobile television broadcasting. With the everyday carry of these devices stems a need for accessories which are adapted to facilitate the portability and use of these electronic devices. Although many accessories are presently available, there has yet to be suggested an accessory for ergonomic attachment of a portable electronic device to the hand or wrist of a user, such that a given device may securely attach and rest along the users hand or wrist while maintaining a stress free and ergonomic anatomical state.

Certain music players, such as MP3 players, have evolved into widespread use during workouts and other activities. Certain armbands or straps have become available for attaching iPods and other MP3 players to the bicep of a user, specifically for use during a workout. For example, U.S. Patent Application Publication No. US 2007/0261703 discloses an arm band for attaching a portable music player to the arm of a user. Although this application discloses attachment of a portable device to a user, the disclosed embodiments fail to recognize the need to attach a device to a users hand or wrist such as to offer ergonomic solutions enabling prolonged use and visual interaction with a portable device. In fact, there has yet to be provided an accessory for attaching a portable device to the wrist of a user for enabling ergonomic attachment and enabling prolonged audio and visual interaction between a user and a portable electronic device. Still further, there has yet to be such an accessory which adapts to one or more fingers of a user to provide stability and ergonomic attachment to the hand or wrist of a user.

Many users have found that holding a portable electronic device requires unnatural contortion of anatomical features; specifically curling and rotating of the fingers, wrist, and forearm muscles. With extended use, a user's joints and muscles can become sore and even injured. This result is largely due to the prolonged contortion of finger joints, wrist, and forearm muscles. There is therefore a need for a solution, such that a user of a portable electronic device may operate the device for prolonged periods of time and without anatomical strain on muscles and tendons.

A solution to the aforementioned problems will further be required to meet cost requirements and affordability, stylistic and aesthetic requirements, durability and portability, low impact with cellular reception or minimized signal interference, among other things.

### SUMMARY OF THE INVENTION

Solutions to the aforementioned requirements are provided in certain embodiments of the invention, wherein an ergonomic band is applied to an external portion of a portable electronic device. The ergonomic band includes a stretchable material extending from a first position to a second position along the length of the portable electronic device, or an article adapted for attachment therewith. The ergonomic band may further include one or more slits for interweaving at least one finger of a user for providing additional stability to the user.

In certain preferred embodiments, the ergonomic band is attached to a rear surface of a portable electronic device. Alternatively, the ergonomic band may be attached to a rear surface of a case or sleeve, wherein the case or sleeve is adapted to attach to the portable electronic device.

In one embodiment, the ergonomic band includes a slit for interweaving one or more fingers for additional stability and ergonomic attachment of the portable electronic device to the hand or wrist of a user. Alternatively, the ergonomic band may include two or more slits. Furthermore, the band may comprise a plurality of substantially parallel strings or material portions, such that a number of slits may be provided for added stability and controlled attachment to the hand or wrist of a user.

The ergonomic band can include a first adhesive portion, a stretchable material extending outwardly from the first adhesive portion, and a second adhesive portion attached to the stretchable material at a position opposite of the first adhesive portion. Multiple adhesive portions can be attached to the stretchable material. In this embodiment, the ergonomic band is adapted to attach to a portable electronic device at one or more adhesive portions; or alternatively the ergonomic band may attach to a case adapted for attachment with said portable electronic device.

In an alternative embodiment, the ergonomic band may include a length of stretchable material attached to a first attachment rod at a proximal end and a second attachment rod at a distal end, such that the first attachment rod is disposed substantially parallel to the second attachment rod at opposite ends of the stretchable material. In this embodiment, the ergonomic band is adapted to be detached and re-engaged to one of the portable electronic device or a case designed for attachment therewith. When the ergonomic band is detached, a belt clip or other clip may attach to the portable electronic device or case adapted for attachment therewith.

In yet another embodiment, a case is provided having a first slot and a second slot disposed at opposite ends of the cell phone case; a stretchable ergonomic band extends through the slots to form a case having an attached ergonomic band. In a variation of this embodiment, two or more ergonomic bands can extend through respective slot pairs to form a case having one or more ergonomic bands extending therefrom.

### BRIEF DESCRIPTION OF THE DRAWINGS

Other key features and embodiments of the invention will become apparent to one having ordinary skill in the art upon reviewing the detailed description, and particularly when review in conjunction with the appended drawings, wherein:

FIG. 1 illustrates an ergonomic band for attachment to a portable electronic device, the band including a first adhesive portion, a second adhesive portion, and a length of stretchable material disposed therebetween; wherein a slit is provided along a portion of the stretchable material for interweaving one or more fingers of a user.

FIGS. 2(a-b) illustrate an ergonomic band attached to a reversible case such that the band can be configured along an external surface of the case for enabling user interaction; or alternatively the band can be configured inside the reversible case such that the band can be substantially captivated between the portable electronic device and the reversible case adapted for attachment therewith.

FIG. 3 is a perspective view of the ergonomic band of FIG. 1 having a first adhesive portion, a second adhesive portion, and a length of material disposed therebetween; the length of material including a slit for introducing one or more fingers of a user.

FIG. 4 illustrates the ergonomic band of FIGS. 1 and 3 as attached to a rear surface of a portable electronic device.

FIG. 5 illustrates an ergonomic band for attachment to a portable electronic device, the band including a first adhesive portion, a second adhesive portion, and a length of stretchable material disposed therebetween; wherein a slit is disposed along a substantial portion of the stretchable material for interweaving one or more fingers of a user.

FIG. 6 illustrates the ergonomic band of FIG. 5 as attached to the rear surface of a case adapted for attachment to the portable electronic device.

FIG. 8 illustrates a perspective front view of a portable electronic device housed within a case, wherein the case includes an ergonomic band attached at a rear surface thereof.

FIG. 7 illustrates an exploded view of a portable electronic devices and device case having an attached ergonomic band.

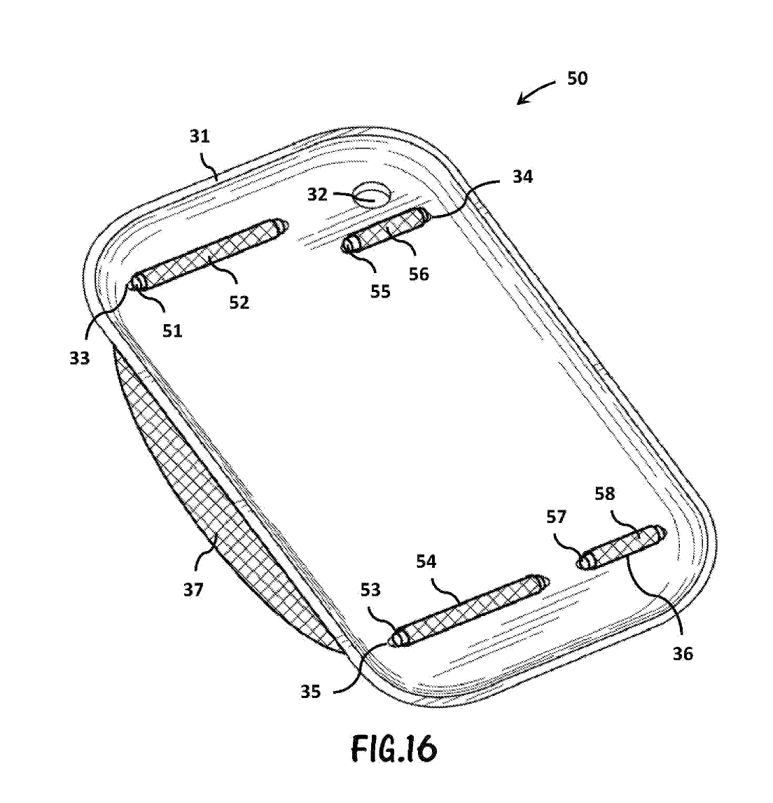

FIG. 8 illustrates an alternative embodiment comprising a first attachment rod, a second attachment rod, and a length of stretchable material disposed therebetween; the attachment rods are configured to engage one of a portable electronic device or a case adapted for attachment therewith at a pair of attachment slots.

FIG. 9 is an exploded view of an alternative embodiment including an ergonomic band attached to a pair of attachment rods, and a rear portion of a portable electronic device or case adapted to receive the pair of attachment rods at a pair of attachment slots; wherein the ergonomic band is configured for detachment and re-engagement with the device or case, and wherein a belt clip or other clip may be attached to the device or case when the ergonomic band is detached.

FIG. 10 is a perspective view of an ergonomic band attached to a portable electronic device, the ergonomic band includes a slit extending along a portion of the length of the ergonomic band.

FIG. 11 is a perspective view of an ergonomic band attached to a portable electronic device; the ergonomic band includes a slit extending along substantially an entire length of the ergonomic band.

FIG. 12 illustrates an ergonomic band including a length of stretchable material disposed between a first adhesive portion and a second adhesive portion; the band includes a notch for conforming about a device port or camera accessory.

FIG. 13 illustrates a rear view of a case for use with a portable electronic device; the case includes a number of slot pairs, wherein each slot pair contains a first slot disposed at a first end of the case and a second slot disposed at a second end of the case opposite of the first end.

FIG. 14 further illustrates the case of FIG. 13, wherein a first ergonomic band extends between a first slot pair, and a second ergonomic band extends between a second slot pair.

FIG. 15 illustrates an interior portion of a case according to one preferred embodiment of the invention, wherein a first ergonomic band extends between a first slot pair and is attached to itself, and wherein a second ergonomic band extends between a second slot pair and is attached to itself.

FIG. 16 illustrates an interior portion of a case according to one preferred embodiment of the invention, wherein each end of a two ergonomic bands are individually attached to a rod, and the rod is adapted to maintain each attached end of the respective ergonomic band behind a slot.

### DETAILED DESCRIPTION

In the following description, for purposes of explanation and not limitation, details and descriptions are set forth in order to provide a thorough understanding of the present invention. However, it will be apparent to those skilled in the art that the present invention may be practiced in other embodiments that depart from these details and descriptions without departing from the spirit and scope of the invention. Certain embodiments will be described below with reference to the drawings wherein illustrative features are denoted by reference numerals.

In certain embodiments of the invention, an ergonomic band is provided for use with a portable electronic device. The ergonomic band is adapted to receive and interweave with one or more of the index, thumb or middle fingers of a user, such that the portable electronic device can be ergonomically attached to the wrist or hand of a user and rotationally adjustable with slight movements of the one or more received fingers. Once attached to the wrist or hand of a user, the portable electronic device can be ergonomically positioned for enabling visual interactive use between the user and the device while protecting anatomical features from strain or stress resulting from prolonged use of the device.

For example, many users of portable electronics operate these devices on airplanes. Furthermore, most airplanes offer limited seat width and minimum passenger space and thus constrain a user's ability to naturally handle a portable electronic device while seated in an airplane. During a multiple hour flight, the user may experience stress or strain related to the contortion of anatomical features such as joints, muscles, and tendons in the hand and wrist from naturally holding the device within the confined space of an airline seat. In this extreme example, a user may observe pain and discomfort with prolonged use of his or her portable device. Trains, automobiles, and even chairs and couches tend to inflict similar pains and discomforts upon a user with prolonged use of a portable device.

The present invention, in certain preferred embodiments, provides a means for effectuating prolonged use of portable electronic devices without the pain and stress of joints, muscles, and tendons in the hand and wrist.

It should be understood that although detailed embodiments are described and illustrated, these embodiments are not intended to limit the scope of the invention, and that additional obvious variants will become apparent to those having skill in the art.

In one embodiment of the invention as illustrated in FIG. 1, an accessory is provided for use with a portable electronic device such as a cellular phone, PDA, portable multimedia device, iPhone, iPod, iPad, Kindle, Blackberry, and the like. The accessory includes an ergonomic band 1 comprising a length of stretchable material 3 extending from a first end to a second end. The stretchable material is attached to a first adhesive portion at the first end, and is further attached to a second adhesive portion 4 at a second end. The adhesive portions generally include a surface of material having at least a portion of the surface coated with an adhesive or bonding agent. The ergonomic band 1 can therefore become attached to a portable electronic device by affixing each of the adhesive portions of the ergonomic band to a surface, such as the rear surface of a portable electronic device or device case 5.

The ergonomic band 1 further comprises one or more slits 2 extending along a length of the stretchable material such that the ergonomic band is adapted to receive one or more fingers of a user. The slit may extend along a portion of the ergonomic band, or up to an entire length of the ergonomic band. The slit provides a mechanism of stability, control, and adjustment which can be effectuated by discrete movements of the one or more received fingers of a user. A user can therefore comfortably and effectively maintain stability and position of a portable electronic device attached to the hand or wrist of the user. The slit may further be capped by stitching or fusing about the edges of the slit such that fraying may be prevented. Two or more slits may further be incorporated for dynamic positioning and control of the attached portable electronic device.

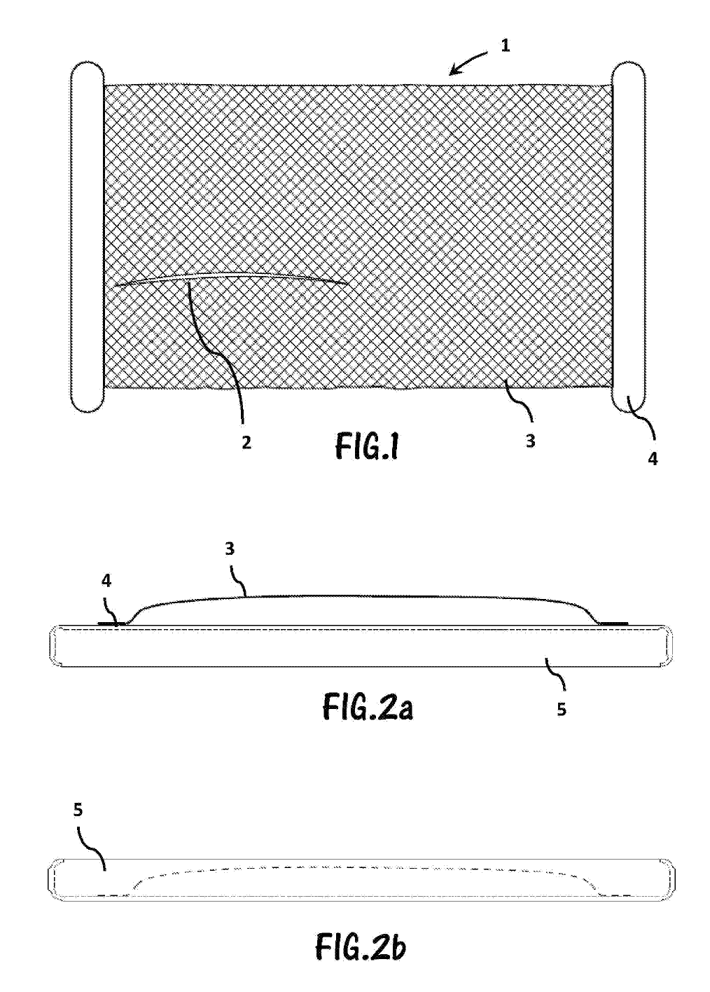

In certain embodiments of the invention, a reversible case is provided as illustrated in FIGS. 2(a-b). The reversible case 5 may comprise a pliable material such as a polymer or gel like composition molded to substantially conform to a portable electronic device. An ergonomic band is attached to a surface of the reversible case. The case 5 may be configured to provide the ergonomic band on an exterior surface of the portable electronic device. Alternatively, the reversible case 5 can be configured to substantially confine the ergonomic band within an interior portion of the case such that the ergonomic band may become substantially captivated between the reversible case and attached portable electronic device.

In one embodiment, a reversible case is injection molded with a pliable polymer composition. The reversible case includes hinges formed as crevasses having less material than bulk portions of the reversible case. Because the hinges comprise less bulk material, the case is substantially more pliable at the hinges, and is therefore adapted to reversibly conform to a portable electronic device. The case may further include one or more apertures for exposing electronic ports such as charging ports, memory ports, and the like.

FIG. 2a illustrates a reversible case 5 in a first state wherein the reversible case is configured with the ergonomic band exposed on an exterior surface of the device case.

FIG. 2b illustrates the reversible case 5 of FIG. 2a configured in a second state wherein the ergonomic band is substantially captivated within an inner portion of the device case. The case may optionally comprise a slot attachment for attaching a belt clip or other clip such that a user may wear the reversible case using an optional clip. Where an optional clip is provided, it is beneficial to locate the slot attachment on a surface opposite of that which the ergonomic band is attached.

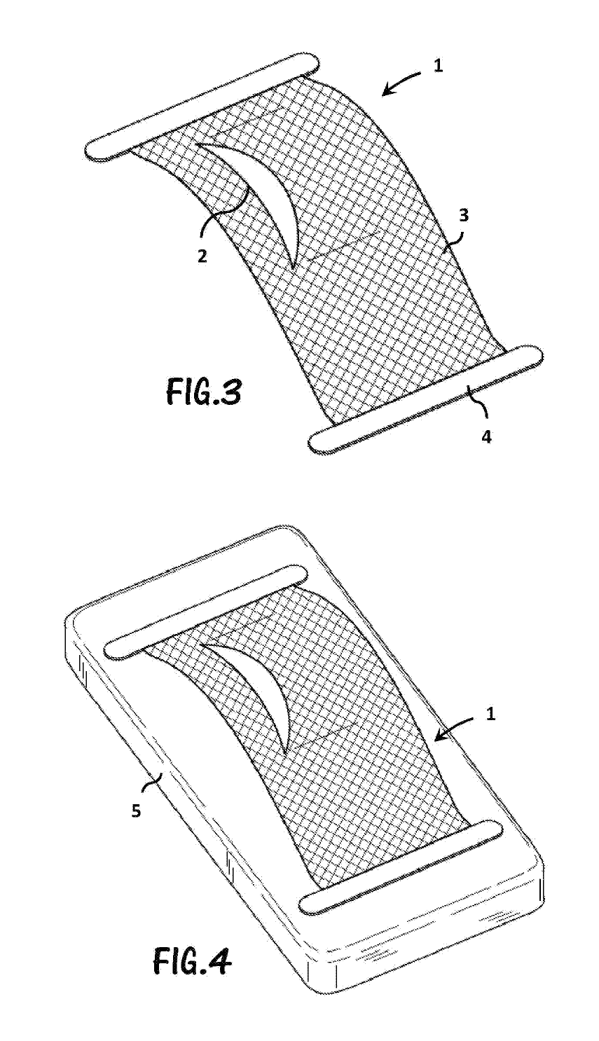

FIG. 3 is a perspective view of an accessory for use with a portable electronic device according to certain embodiments of the invention, wherein the accessory comprises an ergonomic band 1 having a length of material 3 extending from a first adhesive portion to a second adhesive portion 4. The first adhesive portion is disposed at an end opposite of the second adhesive portion 4. Each of the first and second adhesive portions are aligned substantially parallel. It can be said that the first adhesive portion is disposed at a proximal end of the ergonomic band, and that the second adhesive portion 4 is disposed at a distal end of the ergonomic band. As further illustrated by FIG. 3, the accessory comprises a slit 2 disposed along a length of the stretchable material. The slit forms an opening upon expansion of the stretchable material from a first length to a second length such that one or more fingers of a user may be received at the slit and interweaved with the ergonomic band. The accessory can be attached to a portable electronic device at a rear surface such that a screen of the portable electronic device remains unobstructed. Alternatively, the accessory can be attached to a rear surface of a device case.

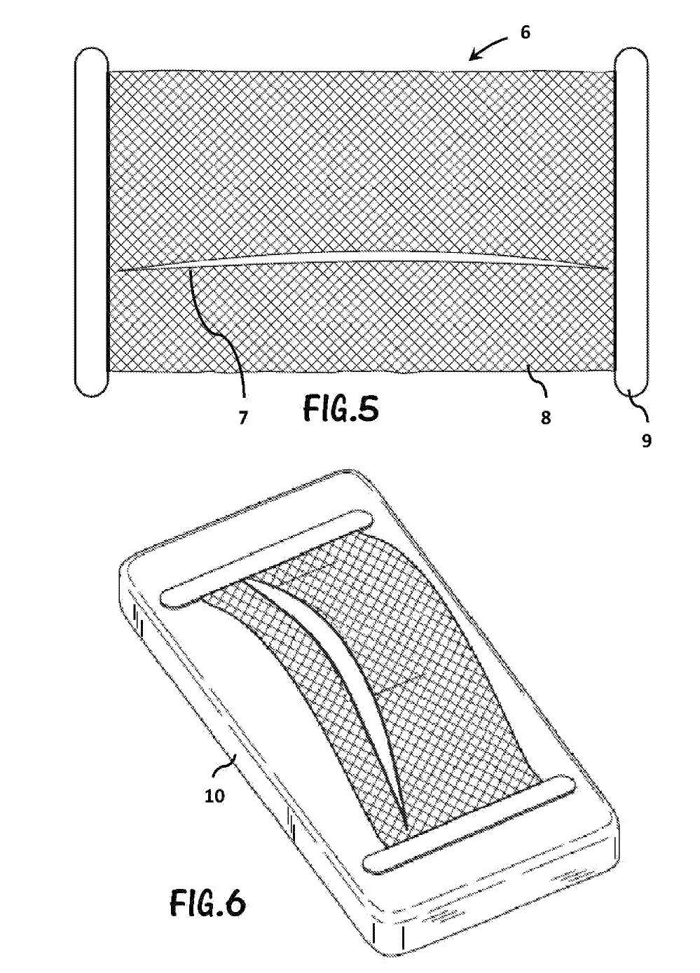

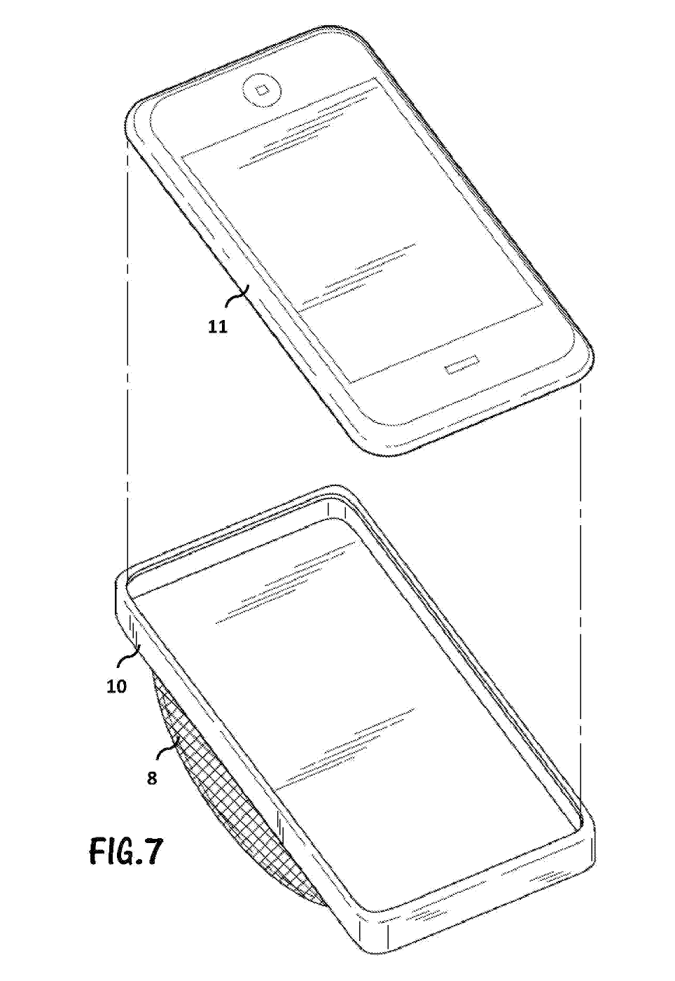

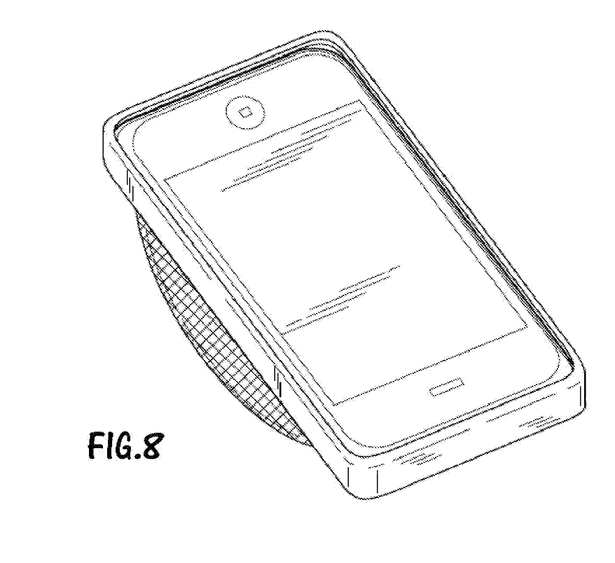

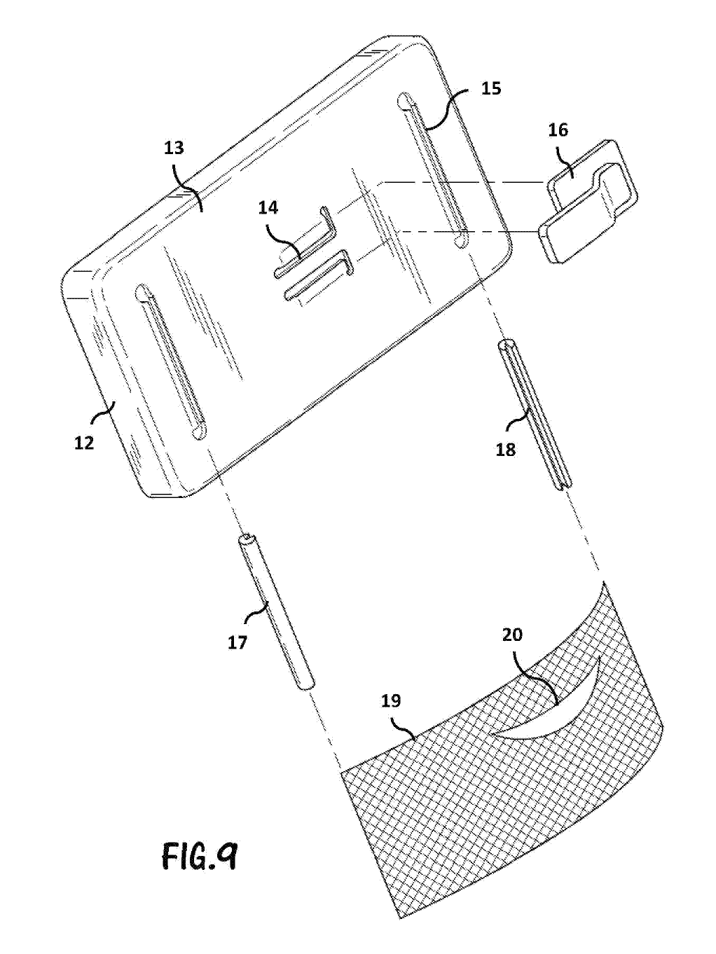

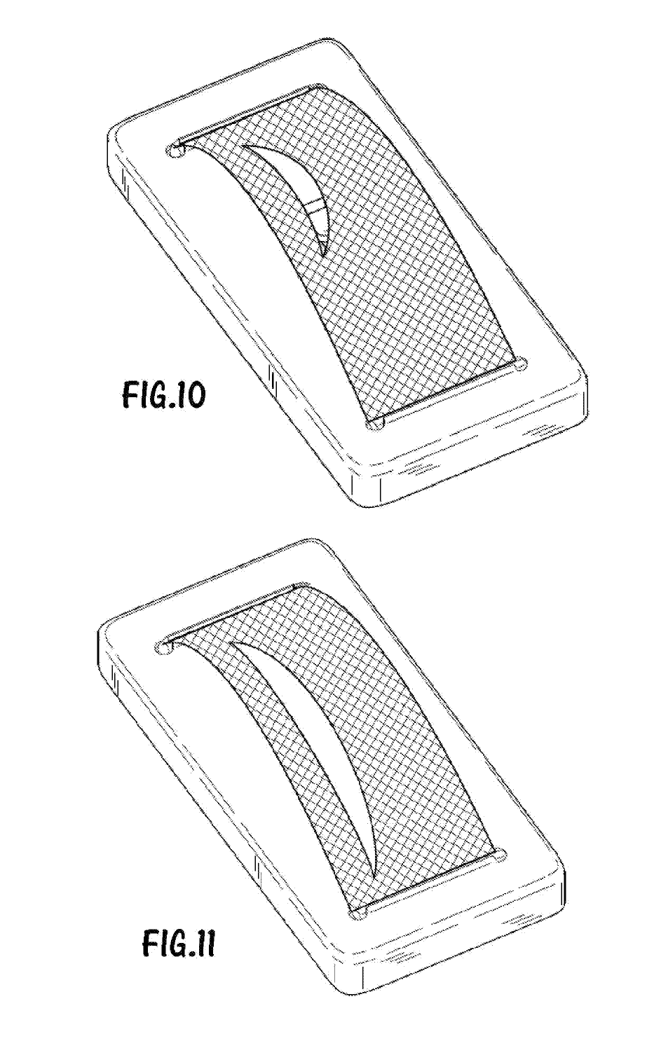

FIG. 4 illustrates an accessory 1 attached to a rear portion of a portable electronic device 5. Here, the accessory includes a first adhesive portion attached at a first end at the rear surface of the device. The accessory further includes a second adhesive portion attached to a second end at the rear surface of the portable electronic device. The ergonomic band extends from the first end to the second end and includes a slit extending along a portion of the length of the band.

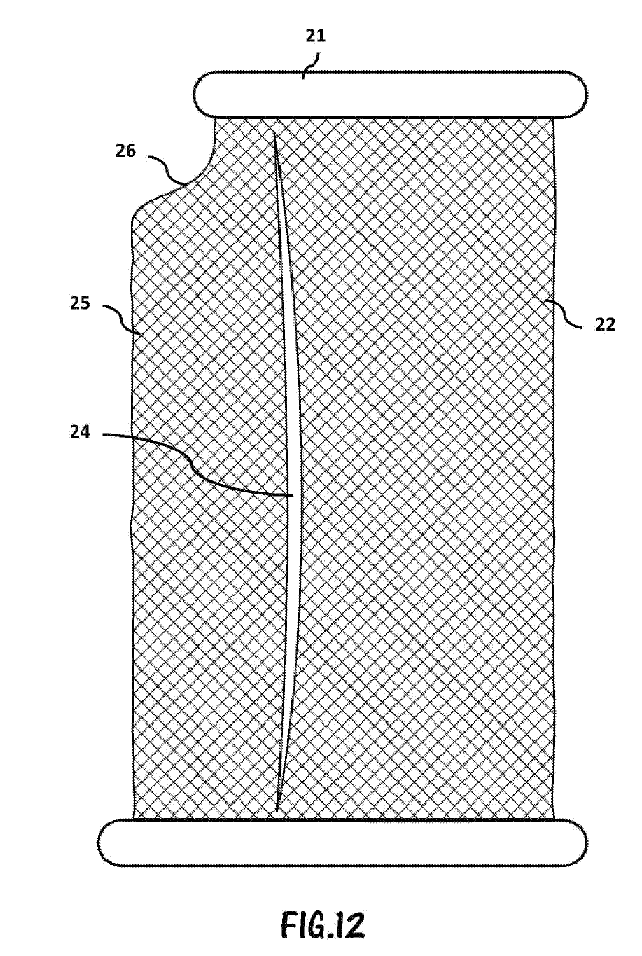

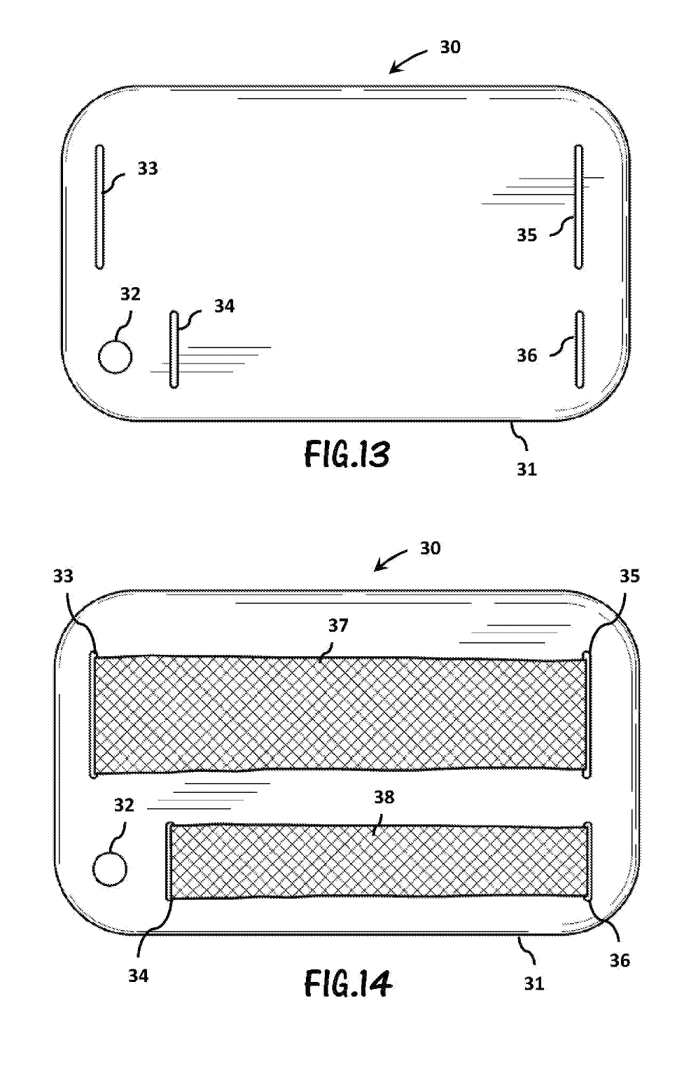

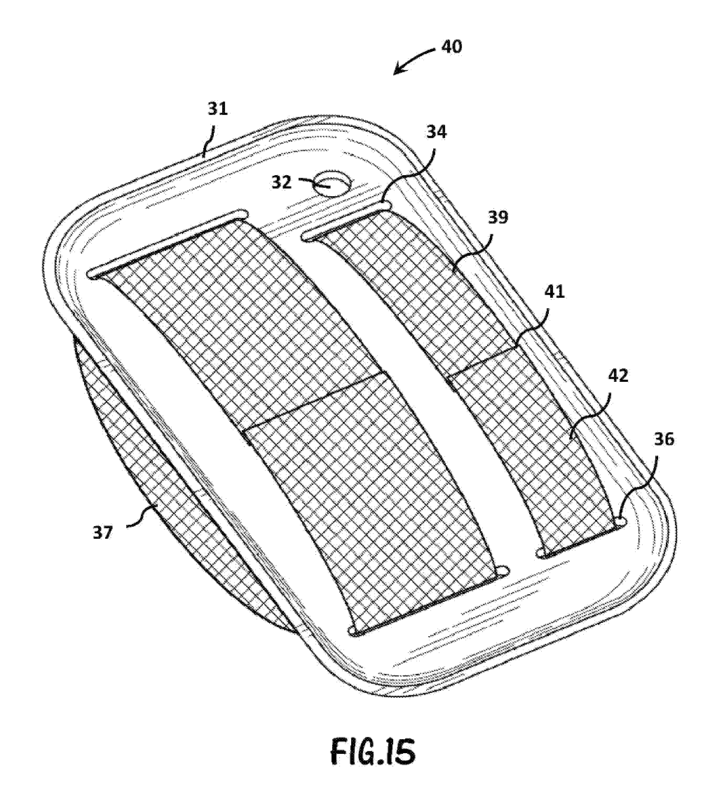

In one preferred embodiment, the slit is of the ergonomic band is configured to extend along a substantial length of the band, such that the slit is adapted to receive several fingers, or an entire hand, or wrist of a user. As illustrated in FIGS. 5-6 an ergonomic band 6 includes a length of stretchable material 8 extending from a first adhesive tab 9 to a second adhesive tab. The stretchable material further includes a slit 7 extending along a length of the stretchable material between the tabs, wherein the slit extends substantially entirely along the length of stretchable material. The ergonomic band 6 can be adhesively attached to a portable electronic device, or device case 10.

In certain other embodiments of the invention, the ergonomic band is attached to a case at a rear surface thereon. The case can be any case adapted to receive and attached to a portable electronic device. FIG. 7 illustrates an exploded view of a device case 10 and received portable electronic device 11. An ergonomic band 8 extends from a top rear portion of the device to a bottom rear portion of the device such that a users hand or wrist may be received by the ergonomic band substantially perpendicular to the device. When expanded, the band conforms around the hand or wrist of a user, such that the portable electronic device may be positioned at least partially perpendicular to the axis of the users arm.

FIG. 8 is a top perspective view of a portable electronic device received within a device case according to the embodiment of FIG. 7. The stretchable material can be divided by the slit such that a first portion is defined along a left side of the slit and a second expandable portion is defined along a right side of the slit. Where more than one slit is incorporated into the stretchable material, multiple expandable portions are disposed between said slits along the length of the stretchable material. Each of the expandable portions is adapted for individual expansion from a first length to a second length, wherein the second length is greater than the first length. The ergonomic band is therefore adapted to substantially conform to an inserted hand of a user.

In yet another embodiment, the ergonomic band includes a length of stretchable material, such as a mesh, elastic fabric, polymer sheet, or a plurality of parallel expandable filaments. The stretchable material is further attached to a first attachment rod at a first end and a second attachment rod at a second end opposite of the first end. The attachment rod can be a rigid elongated rod comprising a slot extending along the length of the rod. The stretchable material can be partially inserted and attached to the slot of the elongated attachment rod using an adhesive or bonding agent.

The elastic band can be removably engaged with a portable electronic device or device case 13 at a pair of attachment slots 12; 15. The attachment slots comprise elongated slots adapted to receive an attachment rod 17; 18. FIG. 9 illustrates an exploded view of the accessory according to an embodiment of the invention. The ergonomic band includes a length of stretchable material 19 expandable from a first length to a second length and is attached to a first attachment rod 17 at a first end and a second attachment rod 18 at a second end opposite of the first end. The stretchable material 19 includes a slit 20 disposed along at least a portion of the length of stretchable material. The stretchable material 19 and attached rods 17; 18 comprise the ergonomic band, and are collectively configured for removable engagement with a pair of attachment slots 12; 15.

An optional clip 16 may be attached to a slot attachment 14 when the ergonomic band is removed from the case. In at least one embodiment, the device or device case can be configured for optional use with an ergonomic band or a clip such as a belt clip.

FIG. 10 illustrates a device case comprising a pair of attachment slots and an attached ergonomic band wherein the elongated attachment rods of the ergonomic band are slideably engaged with the pair of attachment slots. The ergonomic band can be slideably removed from the attachment slots, rotated about the length of the stretchable material, and re-engaged with the attachment slots such that the slit can be altered from a right hand to a left hand position, and therefore accommodate right handed as well as left handed users. The ergonomic band can therefore be adapted for ambidextrous use.

FIG. 11 illustrates a perspective view of an ergonomic band attached to a portable electronic device, the ergonomic band includes a slit extending along substantially an entire length of the ergonomic band. It is important to note that the slit may extend a partial length of the ergonomic band, or extend up to an entire length of the ergonomic band.

In yet another embodiment of the invention, an ergonomic band is provided, the ergonomic band including a first length of stretchable material and a second length of stretchable material, wherein the first length of stretchable material is attached to a rear portion of a portable electronic device or a device case and the second length of stretchable material is attached substantially near the first length such that a slit is formed therebetween. The second length of material may be any length up to that of the first length of stretchable material; i.e. the second length of stretchable material may be equal or less than the first length of stretchable material. Furthermore, the first and second lengths of stretchable material may have similar or different widths and thicknesses. The ergonomic band can be configured for wearing a portable electronic device in any position on a users hand or wrist by configuring the length of the slit, the length, thickness, and width of the portions or lengths of stretchable material, etc.

The ergonomic band may be aligned in any fashion with the rear portion of an electronic device such that a users hand or fingers may be received through the ergonomic band. For example, the ergonomic band may be disposed along the length of the electronic device. Alternatively, the ergonomic band may be disposed along a width of the portable electronic device.

The ergonomic band may be shaped to conform around certain features of the portable electronic device, such as a camera, switch, electronic port, and the like. FIG. 12 illustrates an ergonomic band, including a length of stretchable material extending from a first adhesive tab 21 to a second adhesive tab 23. The first and second adhesive tabs are coated with an adhesive formulation or glue. The first adhesive tab 21 has a first length less than the length of the second adhesive tab 23. The stretchable material includes a slit 24 extending substantially entirely along the length of stretchable material from the first tab 21 to the second tab 23. The stretchable material further includes a first portion 25 disposed on a first side of the slit, and a second portion 22 disposed on a second side of the slit. The ergonomic band is further adapted with a notch 26 configured to expose one of an electronic port, camera, or other device accessory upon attachment of the ergonomic band to the device. The notch can be configured anywhere on the ergonomic band such as to allow a full access and operation of device accessories and device ports.

In another preferred embodiment of the invention as described in FIGS. 13-15; a portable electronic device case is provided, the device case including one or more ergonomic bands extending along a length of the case.

As illustrated in FIG. 13, the device case includes a plurality of slots disposed at or near opposite ends, or corners, of the device case. A first slot pair includes a first slot 33 and a second slot 35, wherein the first and second slots are disposed at opposite ends of the device case 31. The first slot pair may be disposed at opposite ends along a length of the device case, as shown, or alternatively they may be disposed along a width of the device case 31. The first and second slots of the first slot pair may be fixed at a distance L₁ therebetween. The device case further includes a second slot pair comprising a third slot 34 and a forth slot 36, wherein the third and fourth slots are disposed at opposite ends of the device case 31. The third and fourth slots may be fixed at a distance L₂ therebetween. The distances L₁ and L₂ may be similar or differentiated. Each band, and respective slot can be configured for a different width or thickness, or alternatively the bands may be substantially similar in size.

FIG. 14 illustrates a rear view of the device case of FIG. 13 with attached ergonomic bands. A first ergonomic band 37 extends between the first slot 33 and second slot 35 of the first slot pair. A second ergonomic band 38 extends between the third slot 34 and fourth slot 36 of the second slot pair. One or both bands may be configured about a device accessory, such as a camera aperture 32 as illustrated in FIG. 14.

There are many designs that may be implemented to fabricate the accessory of FIG. 14; of those two particular embodiments are illustrated for manufacturing a case having desired elasticity or the ergonomic band.

In a first example, as illustrated by FIG. 15, an interior portion or side of the device case includes a first slot and a second slot of a first slot pair, a third slot 34 and fourth slot 36 of a second slot pair, as described above. A first ergonomic band 37 extends between the first slot pair. A second ergonomic band having a first end 39 extending through a third slot 34, and a second end 42 extending through a fourth slot 36, forms an annular band attached to itself at opposite ends, wherein the first end 39 and second end 42 are attached at a seam 41. The first band is substantially configured similar to the second band, such as to form an annular ergonomic band extending through the first slot pair. One particular advantage of this embodiment includes maximized length of stretchable material, such that the band is adapted to expand to receive a user's hand or wrist, and is adapted to fully retract with maximum recoil. The ergonomic band may include a length of stretchable material up to several times the length between the respective slots for receiving the band. During manufacturing, the first and second end can be slightly tensioned prior to attachment to create a band that will conform to the rear surface of the case, or substantially flush therewith when the band is not in use; thereby providing a slim profile.

One or more spacers can be included to offset an interior portion of the case from the rear surface of a portable electronic device. Spacers can include plastic or rubber bumps or molded fabrications which are placed at one or more corners of the interior portion of the device case. In this regard, the spacers allow a small gap between the interior surface of the device case and the portable electronic device for optimizing band stretchability therebetween.

In another example, one or more springs or spring mechanisms can attach an end of the ergonomic band to a fixed portion of the device case at the interior surface. The spring may assist in retracting the band for added stretchability and for improving band to device or band to device case form factor. Using one or more springs, the band may become flush with the device or device case. Alternatively, the band can attach directly to the case.

In a second example, as illustrated in FIG. 16, a first ergonomic band 37 extends through a first slot 33 to a first end 52; the first end is attached to a first rod 51 for maintaining the first end within an interior portion of the device case. The first ergonomic band 37 further extends through a second slot 35 to a second end 54; the second end is attached to a second rod 53 for maintaining the second end within an interior portion of the device case. In this embodiment, the ergonomic band has a length of stretchable material approximately equal to a length between the first slot pair 33; 35. Similarly, a second ergonomic band is configured between a second slot pair 34; 36 in substantially the same manner as the first band.

Several examples have been disclosed herein for providing a device or device case adapted with one or more ergonomic bands for attaching to at least a portion of a users hand or wrist. It should be understood that several other designs may be provided which accomplish substantially the same objective, and that other embodiments not described would be obvious to one having skill in the art. The above examples are set forth for illustrative purposes and are not intended to limit the spirit and scope of the invention. One having skill in the art will recognize that deviations from the aforementioned examples can be created which substantially perform the same functions and obtain similar results. Accordingly, even obvious variations of the aforementioned examples are intended to be within the scope of the invention.

What is claimed is:

1. An accessory for use with a portable electronic device, comprising:
an ergonomic band consisting essentially of a length of stretchable material and at least one slit disposed along at least a portion of said length;
said ergonomic band adapted for attachment to one of a portable electronic device or a case;
wherein said ergonomic band is adapted to receive a hand of a user such that one or more fingers of said user extend through said slit.

2. The accessory of claim 1, wherein said stretchable material comprises a plurality of portions expandable from a first length to a second length, wherein said second length is greater than said first length.

3. The accessory of claim 1, wherein said ergonomic band is attached to a rear surface of a portable electronic device.

4. The accessory of claim 3, wherein said ergonomic band is attached to said rear surface of said portable electronic device at a first adhesive portion and a second adhesive portion.

5. The accessory of claim 4, wherein said first adhesive portion is disposed at a first end of said portable electronic device, and said second adhesive portion is disposed at a second end of said portable electronic device, wherein said second end is opposite of said first end.

6. The accessory of claim 1, wherein said ergonomic band is attached to a rear surface of a case; said case adapted for attachment to a portable electronic device.

7. The accessory of claim 6, wherein said case is reversible.

8. The accessory of claim 7, wherein said ergonomic band is adapted to be disposed on an exterior surface of said reversible case.

9. The accessory of claim 8, wherein said ergonomic band is adapted to be captivated between said reversible case and said portable electronic device.

10. The accessory of claim 1, wherein said ergonomic band is removably engaged with a rear surface of a case; said case adapted for attachment to a portable electronic device.

11. The accessory of claim 10, said length of stretchable material further including a first attachment rod fixed at a proximal end of the stretchable material and a second attachment rod fixed at a distal end of the stretchable material; the first attachment rod adapted to removably engage with a first attachment slot disposed on said rear surface of said case at a first end, the second attachment rod adapted to removably engage with a second attachment slot disposed on said rear surface of said case at a second end, said second end opposite of said first end; wherein said ergonomic band is removably engaged with said case.

12. The accessory of claim 1, wherein said slit extends along about half of said length of stretchable material.

13. An accessory for use with a portable electronic device, comprising:
an ergonomic band having a length of stretchable material extending from a first attachment means to a second attachment means;
said first attachment means including one of an adhesive portion or an attachment rod;
said second attachment means substantially similar to said first attachment means;
said length of stretchable material further comprising one of: a plurality of elastic filaments, one or more portions of stretchable fabric, or one or more elastic polymer sheets;
wherein said length of stretchable material further comprises one or more slits for receiving at least one finger of a user; and
wherein said first and second attachment means are configured to attach said ergonomic band to one of a portable electronic device or a case for attachment to a portable electronic device.

14. An accessory for use with a portable electronic device, comprising:
a case adapted to substantially conform to a portable electronic device, said case having a length and a width;
a first slot disposed at a first end of said device case;
a second slot disposed at a second end of said device case, said second end opposite of said first end; and
an ergonomic band extending between said first and second slots.

15. The accessory of claim 14, wherein said case forms a rear enclosure of a portable electronic device.

16. The accessory of claim 14, wherein said case forms an article for attaching to a portable electronic device.

17. The accessory of claim 16, wherein said ergonomic band includes a first end and a second end.

18. The accessory of claim 17, wherein said first and second ends extend through a first slot pair.

19. The accessory of claim 18, wherein said first end and second end are attached at a seam.

20. The accessory of claim 19, wherein said ergonomic band is characterized by an annular shape.
